(19) United States
(12) Patent Application Publication
(10) Pub. No.: US 2012/0193793 A1
(43) Pub. Date: Aug. 2, 2012

(54) SEMICONDUCTOR DEVICE AND METHOD OF FABRICATING THE SAME

(75) Inventor: Teppei TSUKAMOTO, Kanagawa-ken (JP)

(73) Assignee: Kabushiki Kaisha Toshiba, Tokyo (JP)

(21) Appl. No.: 13/362,622

(22) Filed: Jan. 31, 2012

(30) Foreign Application Priority Data
Feb. 1, 2011 (JP) 2011-019492

(51) Int. Cl. H01L 23/48; H01L 21/768

(52) U.S. Cl. 257/751; 438/653; 257/E23.011; 257/E21.584; 257/E21.577

(57) ABSTRACT

According to an embodiment, a semiconductor device includes a first wiring member, an opening portion and an electrode terminal portion. The first wiring member is provided on a first interlayer insulating film on a semiconductor substrate and used as a wiring layer. The opening portion is provided in a second interlayer insulating film on the first wiring member. The electrode terminal portion is provided on the opening portion and the second interlayer insulating film around the opening portion. In the electrode terminal portion, a barrier metal film in contact with the first wiring member, a seed metal film and a second wiring member are stacked and thus formed in such a manner as to cover the opening portion, and a coating metal film is formed on an upper portion and a side surface of the second wiring member.

### CROSS REFERENCE TO RELATED APPLICATION

This application is based upon and claims the benefit of priority from the prior Japanese Patent Application No. 2011-019492, filed on Feb. 1, 2011, the entire contents of which are incorporated herein by reference.

### FIELD

Embodiments described herein relate to a semiconductor device and a method of fabricating the same.

### BACKGROUND

Along with the progress in the miniaturization of semiconductor elements as well as the achievement of higher integration and lower power consumption of the semiconductor elements, there has been an increasing demand for a reduction in wiring resistance and line-to-line capacitance of wiring used in semiconductor devices such as semiconductor integrated circuits. In order to meet this demand, multilayer wiring using Cu (copper), which has a resistivity relatively lower than conventionally-used Al (aluminum), is often used.

In a case where Cu (copper) wiring is used for an electrode terminal portion (pad portion), there arises a problem that the reliability of a semiconductor device that has been sealed is reduced because of occurrence of a change in quality or the like due to oxidation or contamination of a side surface portion. In addition, when the etching amount of the side surface portion is taken into consideration, there arises a problem that the design rule of the wiring layer is increased.

### BRIEF DESCRIPTION OF THE DRAWINGS

FIG. 1 is a cross-sectional view showing a semiconductor device according to a first embodiment;

FIG. 2 is a cross-sectional view showing a semiconductor device of a comparative example according to the first embodiment;

FIG. 3 is a cross-sectional view showing a semiconductor device of another comparative example according to the first embodiment;

FIG. 4 is a cross-sectional view showing a fabrication process of the semiconductor device according to the first embodiment;

FIG. 5 is a cross-sectional view showing a fabrication process of the semiconductor device according to the first embodiment;

FIG. 6 is a cross-sectional view showing a fabrication process of the semiconductor device according to the first embodiment;

FIG. 7 is a cross-sectional view showing a fabrication process of the semiconductor device according to the first embodiment;

FIG. 8 is a cross-sectional view showing a fabrication process of the semiconductor device according to the first embodiment;

FIG. 9 is a cross-sectional view showing a fabrication process of the semiconductor device according to the first embodiment;

FIG. 10 is a cross-sectional view showing a fabrication process of the semiconductor device according to the first embodiment;

FIG. 11 is a cross-sectional view showing a fabrication process of the semiconductor device according to the first embodiment;

FIG. 12 is a cross-sectional view showing a semiconductor device of a modification;

FIG. 13 is a cross-sectional view showing a fabrication process of a semiconductor device according to a second embodiment;

FIG. 14 is a cross-sectional view showing a fabrication process of the semiconductor device according to the second embodiment;

FIG. 15 is a cross-sectional view showing a fabrication process of the semiconductor device according to the second embodiment;

FIG. 16 is a cross-sectional view showing a fabrication process of the semiconductor device according to the second embodiment; and

FIG. 17 is a cross-sectional view showing a fabrication process of the semiconductor device according to the second embodiment.

### DETAILED DESCRIPTION

According to an embodiment, a semiconductor device includes a first wiring member, an opening portion and an electrode terminal portion. The first wiring member is provided on a first interlayer insulating film on a semiconductor substrate and used as a wiring layer. The opening portion is provided in a second interlayer insulating film on the first wiring member. The electrode terminal portion is provided on the opening portion and the second interlayer insulating film around the opening portion. In the electrode terminal portion, a barrier metal film in contact with the first wiring member, a seed metal film and a second wiring member are stacked and thus formed in such a manner as to cover the opening portion, and a coating metal film is formed on an upper portion and a side surface of the second wiring member.

According to another embodiment, a method of fabricating a semiconductor device includes the steps of forming a first wiring member, forming a first opening portion, stacking and thus forming a barrier metal film and a seed metal film, forming a resist film, burying a second wiring member, forming a clearance, forming a coating metal film, and etching the seed metal film and the barrier metal film. In the step of forming the first wiring member, the first wiring member is formed on a first interlayer insulating film on a semiconductor substrate. In the step of forming the first opening portion, the first opening portion is formed by etching a second interlayer insulating film provided on the first wiring member. In the step of stacking and thus forming the barrier metal film and the seed metal film, the barrier metal film and the seed metal film are stacked and thus formed on the first opening portion and the second interlayer insulating film. In the step of forming the resist film, the resist film having a second opening portion is formed on the first opening portion and the seed metal film around the first opening portion. In the step of burying the second wiring member, a second wiring member in contact with the seed metal film is buried in the second opening portion by using electrolytic plating. In the step of forming the clearance, the clearance is formed between the second wiring member and the resist film by subjecting the resist film to a heat treatment so as to cause the resist film to shrink. In the step of forming the coating metal film, the coating metal film is formed by using electrolytic plating on an upper portion and a side surface of the second wiring member in such a manner as to cover the clearance. In the step of etching the seed metal film and the barrier metal film, the resist film is removed, and the seed metal film thus exposed and the barrier metal film are etched using the coating metal film as a mask.

Hereinafter, further plural examples are described with reference to the drawings. In the drawings, the same numeral indicates the same or similar portions.

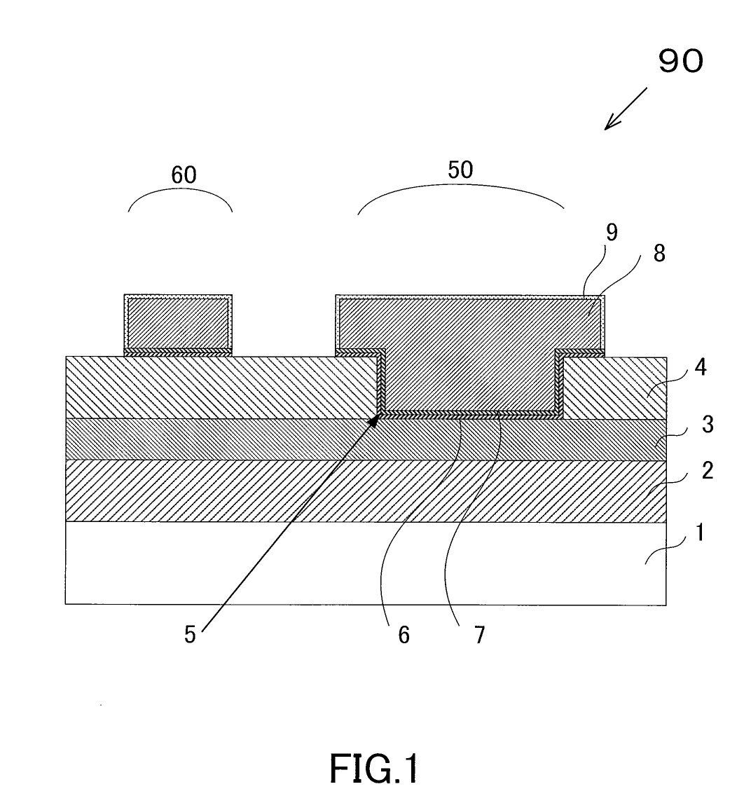

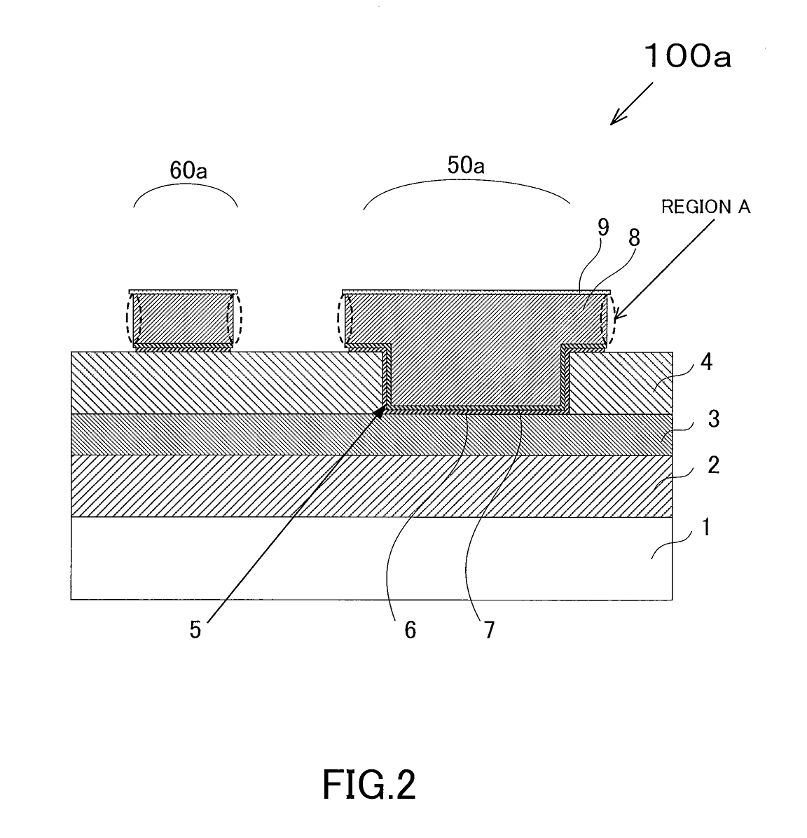

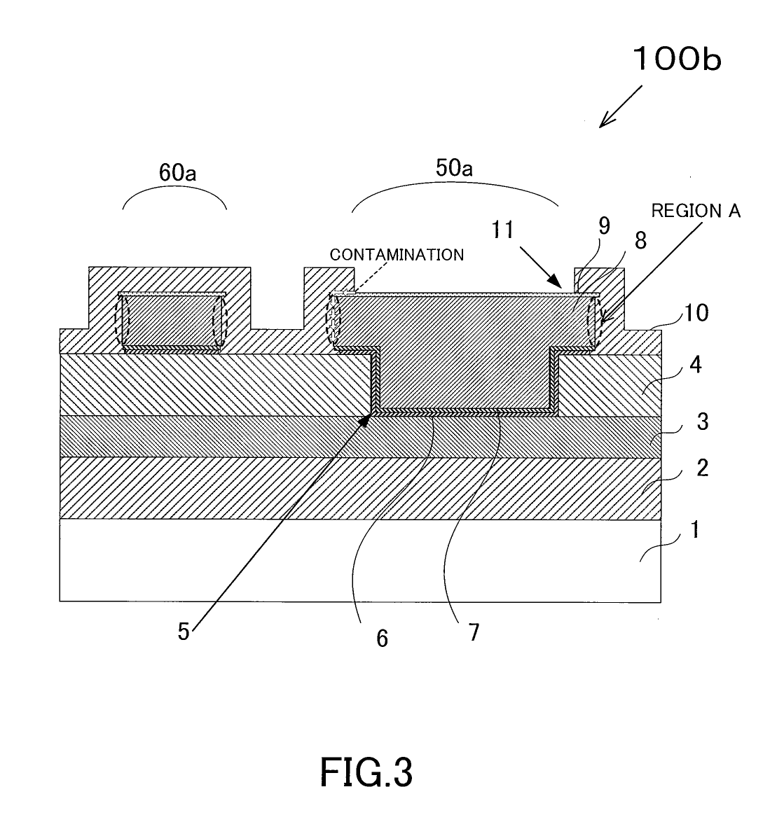

A semiconductor device according to a first embodiment and a method of fabricating the same will be described with reference to the relevant drawings. FIG. 1 is a cross-sectional view showing the semiconductor device. FIG. 2 and FIG. 3 are cross-sectional views showing semiconductor devices of comparative examples, respectively. In the first embodiment, an upper portion and a side surface of an uppermost metal wiring layer made of Cu (copper) are coated with a coating metal film made of Au (gold).

As shown in FIG. 1, a semiconductor device 90 includes a wiring member 3, which is used as a wiring layer, an electrode terminal portion 50, which is connected to the wiring member 3, and a wiring portion 60. The wiring member 3 and the wiring portion 60 are used as wiring for connection to a not-shown circuit provided to the semiconductor device 90, or as power supply wiring. The semiconductor device 90 is resin-sealed while the electrode terminal (pad) portion 50 is connected to an external terminal via a bonding wire using Cu (copper) or Au (gold), for example.

An interlayer insulating film 2 is provided on a semiconductor substrate 1 (first principal surface), which is a silicon substrate. The wiring member 3, which is used as a wiring layer, is provided on the interlayer insulating film 2 (first principal surface). An interlayer insulating film 4 is provided on the wiring member 3 (first principal surface).

A barrier metal film 6 in contact with the wiring member 3, a seed metal film 7, and a wiring member 8 are stacked and thus formed on an opening portion 5, which is opened by etching the interlayer insulating film 4, and the interlayer insulating film 4 around the opening portion 5 (first principal surface). A coating metal film 9 is provided on the upper portion and the side surface of the wiring member 8 of the electrode terminal portion 50.

The barrier metal film 6, the seed metal film 7, and the wiring member 8 are stacked and thus formed on the interlayer insulating film 4 (first principal surface) in the wiring portion 60 while being spaced from the electrode terminal portion 50. The coating metal film 9 is provided on the upper portion and the side surface of the wiring member 8 of the wiring portion 60.

Accordingly, the wiring member 8, which is a metal film having a large thickness in each of the electrode terminal portion 50 and the wiring portion 60, has no exposed region since the lower portion of the wiring member 8 is coated with the barrier metal film 6 and the seed metal film 7 while the upper portion and the side surface of the wiring member 8 are coated with the coating metal film 9.

Note that, a p-SiOC film is used for the interlayer insulating film 2 and the interlayer insulating film 4. A Cu (copper) film is used for the wiring member 3, the seed metal film 7 and the wiring member 8. A TaN (tantalum nitride) film is used for the barrier metal film 6. A Au (gold) film is used for the coating metal film 9. Since the electrode terminal portion 50 is connected to an external terminal via a bonding wire using Cu (copper) or Au (gold), the Cu (copper) film forming the wiring member 8 is formed to have a thickness larger than the wiring member 3 and is provided with a thickness in a range from 5 to 12 μm, for example. Although a Cu (copper) film is used for the wiring member 3, any one of Al (aluminum), Al—Cu and Al—Si—Cu may be used for the wiring member 3, instead.

Cu (copper) is likely to be oxidized, and is likely to be deteriorated and to change in quality due to contamination or the like. Meanwhile, Au (gold) is unlikely to be oxidized, and is less likely to be deteriorated and to change in quality due to contamination or the like. In the first embodiment, the upper portion and the side surface of the wiring member 8, which is made of Cu (copper), in each of the electrode terminal portion 50 and the wiring portion 60 are coated with the coating metal film 9, which is made of Au (gold) (the lower portion of the wiring member 8 is coated with the seed metal film 7 and the barrier metal film 6). Accordingly, it is made possible to greatly suppress oxidation of the wiring member 8, which is made of Cu (copper), and deterioration and a change in quality of the wiring member 8 due to contamination or the like. Thus, the electrode terminal portion 50 and the wiring portion 60 can be made highly reliable.

As shown in FIG. 2, a semiconductor device 100a of a comparative example includes the wiring member 3, which is used as a wiring layer, and an electrode terminal portion 50a, which is connected to the wiring member 3, and a wiring portion 60a. The semiconductor device 100a of the comparative example is different from the semiconductor device 90 of the first embodiment in the electrode terminal portion 50a and the wiring portion 60a. For this reason, only the different portions will be described.

In the electrode terminal portion 50a, the barrier metal film 6, the seed metal film 7, and the wiring member 8 are stacked and thus formed on the opening portion 5 and the interlayer insulating film 4 around the opening portion 5, and the coating metal film 9 is provided on the wiring member 8. The coating metal film 9 has an end portion protruding outward from the wiring member 8 and the seed metal film 7. Each of the wiring member 8 and the seed metal film 7 has an end portion protruding outward from the barrier metal film 6. In the electrode terminal portion 50a, the coating metal film 9 is not provided to a region A of the side surface of the wiring member 8, so that the wiring member 8 is exposed in the region A.

In the wiring portion 60a, the barrier metal film 6, the seed metal film 7, and the wiring member 8 are stacked and thus formed on the interlayer insulating film 4 while being spaced from the electrode terminal portion 50a, and the coating metal film 9 is provided on the wiring member 8. The coating metal film 9 has an end portion protruding outward from the wiring member 8 and the seed metal film 7. Each of the wiring member 8 and the seed metal film 7 has an end portion protruding outward from the barrier metal film 6. In the wiring portion 60a, the coating metal film 9 is not provided to a region A of the side surface of the wiring member 8, so that the wiring member 8 is exposed in the region A.

For this reason, the side surface portion of the wiring member 8, which is made of Cu (copper), is likely to be corroded and oxidized, and the quality of the film is likely to be deteriorated and changed. In addition, in a case where the semiconductor device 100a is sealed, the wiring member 8 changes in quality upon entrance of contamination into the side surface portion of the wiring member 8, thus reducing the reliability of the semiconductor device 100a. Moreover, when the etching amount of the side surface portion is taken into consideration, the design rule of the wiring layer is increased.

As shown in FIG. 3, a semiconductor device 100b of a comparative example is obtained by forming a surface protection film 10 on the semiconductor device 100a and forming an opening portion 11 by etching the surface protection film 10 on the electrode terminal portion 50a.

In this case as well, contamination enters the region A of the side surface of the wiring member 8 from the interface between the surface protection film 10 and the coating metal film 9 via the opening portion 11. Accordingly, the side surface portion of the wiring member 8, which is made of Cu (copper), is likely to be corroded and oxidized, and the film quality of the wiring film 8 is likely to be deteriorated and changed.

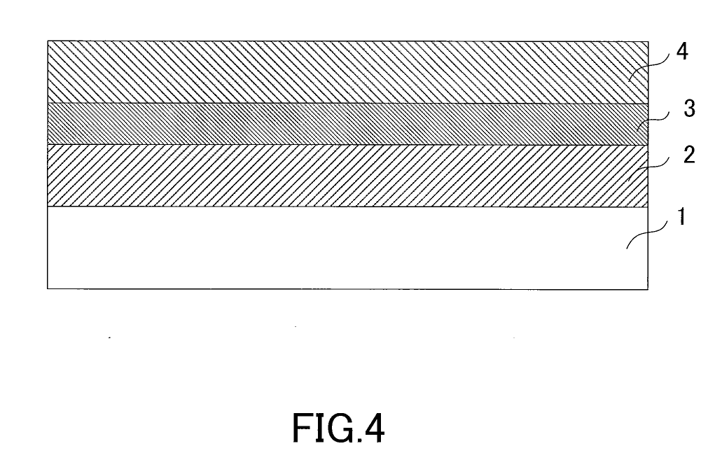

Next, the method of fabricating the semiconductor device will be described with reference to FIGS. 4 to 11. FIGS. 4 to 11 are cross-sectional views each showing a fabrication process of the semiconductor device.

As shown in FIG. 4, after a not-shown active element and a not-shown passive element constituting the semiconductor device 90 are formed on the semiconductor substrate 1, which is a silicon substrate, the interlayer insulating film 2, the wiring member 3, and the interlayer insulating film 4 are sequentially stacked and thus formed on the semiconductor substrate 1.

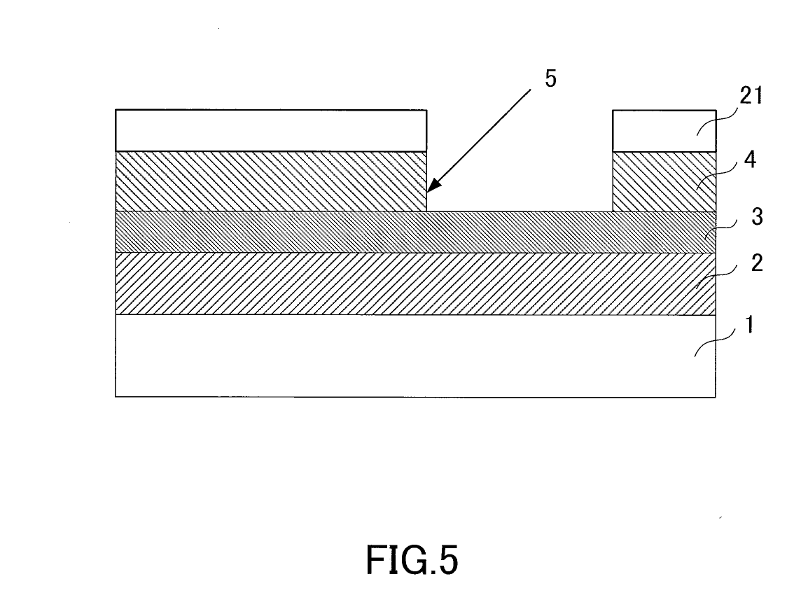

Next, as shown in FIG. 5, a resist film 21 is formed using well-known lithography, and the opening portion 5 is formed by etching the interlayer insulating film 4 using RIE (Reactive Ion Etching), for example, using the resist film 21 as a mask. After removal of the resist film 21, etching residues or the like of the interlayer insulating film 4 are removed by RIE post-processing.

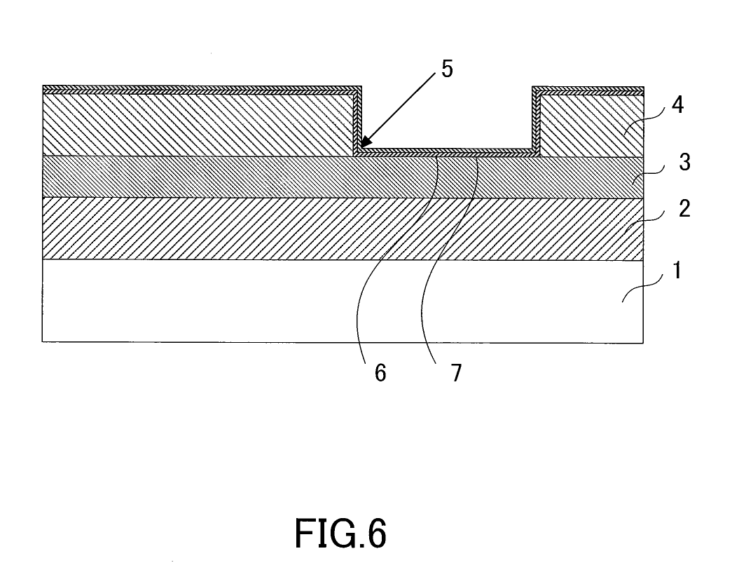

Subsequently, as shown in FIG. 6, the barrier metal film 6 and the seed metal film 7 are stacked and thus formed on the opening portion 5 and the interlayer insulating film 4. Sputtering, for example, is used to form the barrier metal film 6 and the seed metal film 7.

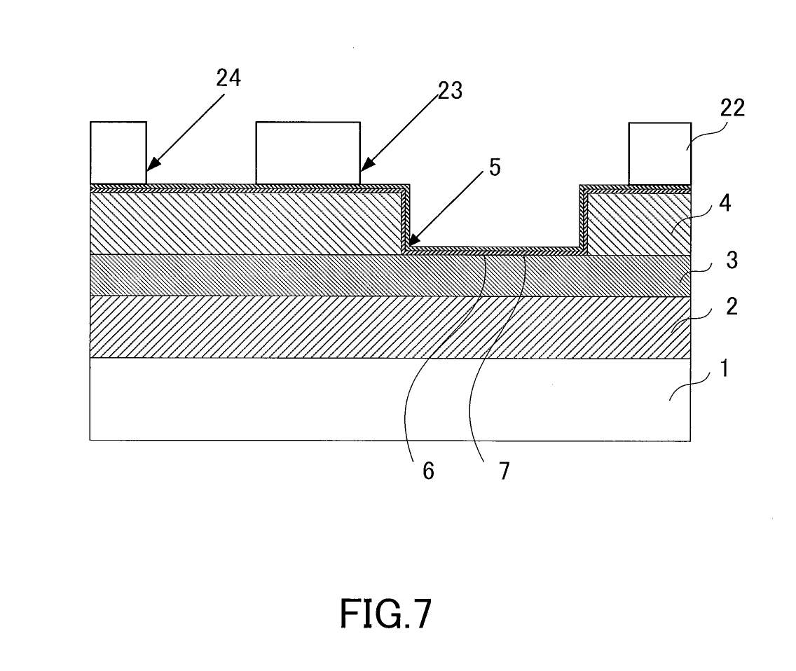

Moreover, as shown in FIG. 7, a resist film 22 is formed using well-known lithography, and an opening portion 23 is provided on the opening portion 5 and the seed metal film 7 around the opening portion 5, and an opening portion 24, which is spaced from the opening portion 23, is provided on the seed metal film 7.

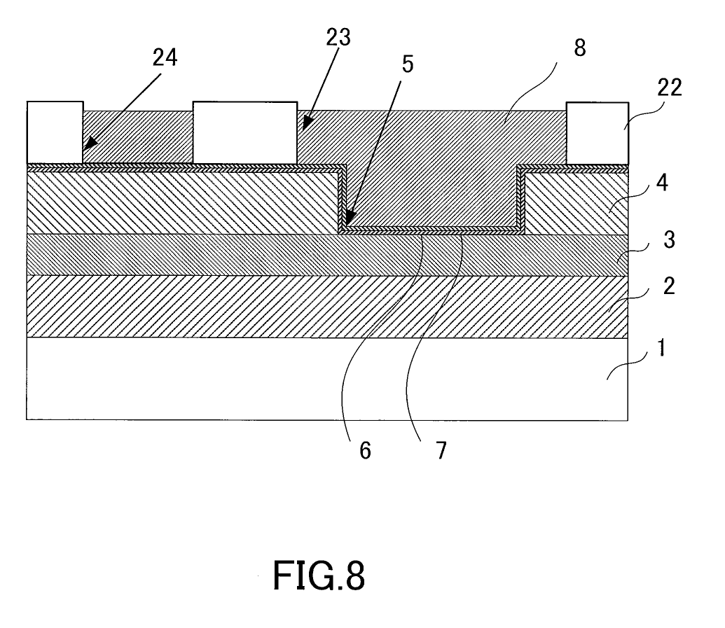

Next, as shown in FIG. 8, the wiring member 8, which is made of Cu (copper), is buried in the opening portion 23 and the opening portion 24 by using first electrolytic plating. The first electrolytic plating is carried out by using a plating solution mainly containing copper sulfate, for example, under the conditions where the temperature is 60° C. and the current density is 3 to 50 mA/cm².

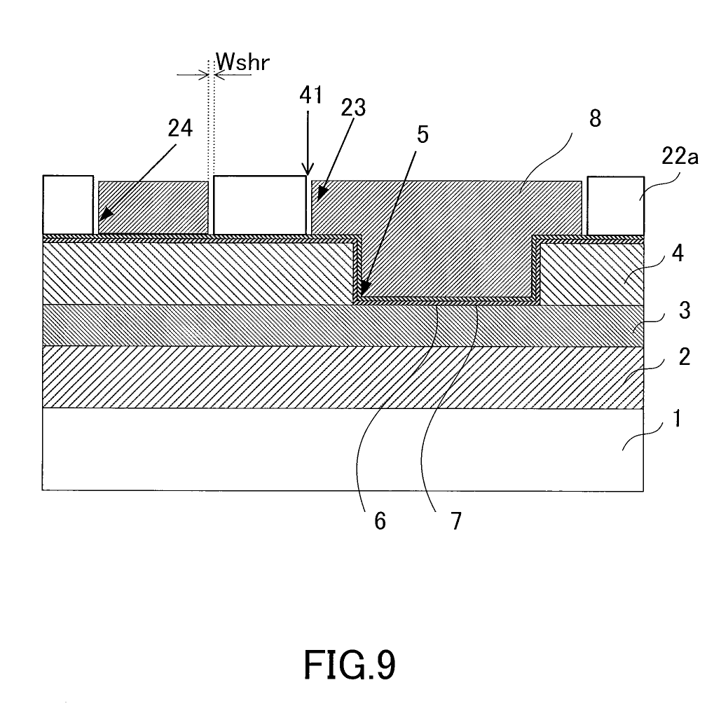

Subsequently, as shown in FIG. 9, the resist film 22 is subjected to a heat treatment and thereby caused to shrink. Thus, a resist film 22a, which is obtained as a result of causing the resist film 22 to shrink, is formed. Because of the heat treatment on the resist film 22, the resist film 22a and the wiring member 8 are spaced from each other just by a resist shrink width Wshr, and a clearance 41 is formed between the resist film 22a and the wiring member 8.

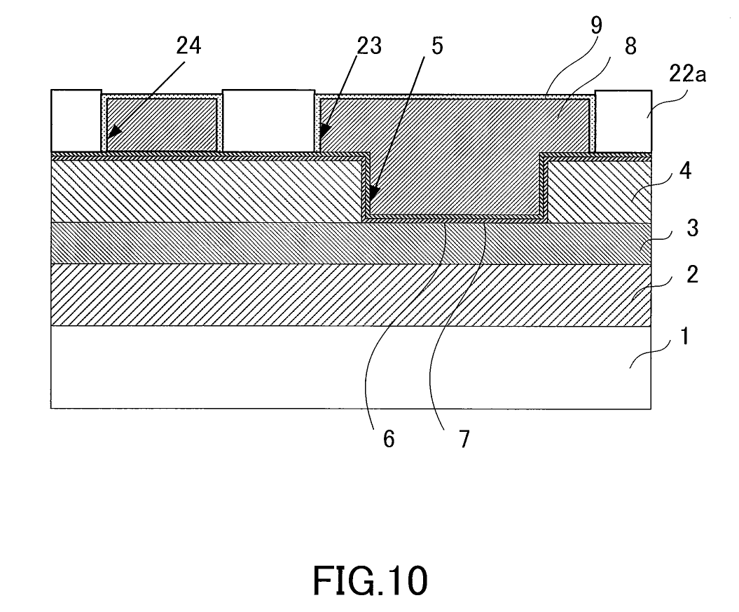

Further, as shown in FIG. 10, the coating metal film 9, which is made of Au (gold), is formed on the upper portion and the side surface of the wiring member 8 in such a manner as to cover the clearance 41 by using second electrolytic plating. The second electrolytic plating is carried out by using a sodium gold sulfite based plating solution or a sodium gold sulfite and thiosulfate based mixed plating solution, for example, under the conditions where the temperature is 60° C. and the current density is 1 to 20 mA/cm².

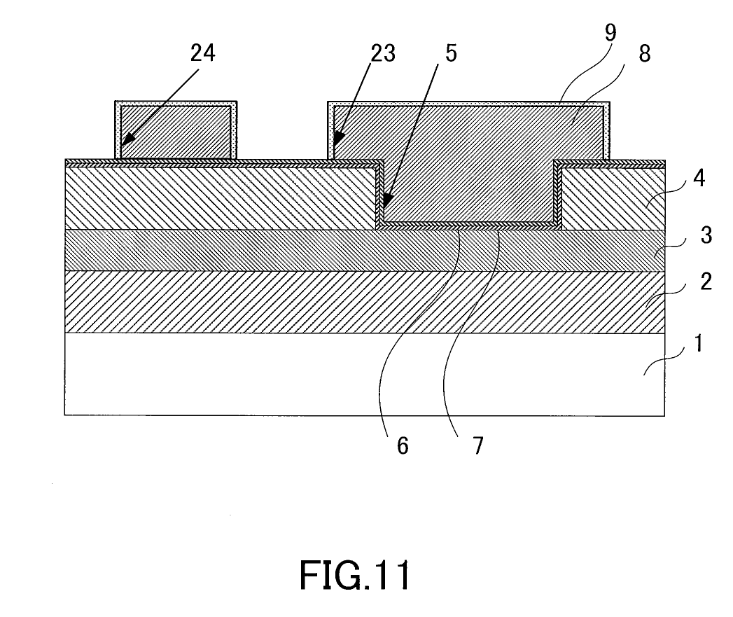

Next, as shown in FIG. 11, after removal of the resist film 22a, the seed metal film 7 and the barrier metal film 6 are etched using the coating metal film 9, which is made of Au (gold), as a mask. Although dry etching is used in etching the seed metal film 7 and the barrier metal film 6, wet etching may be used as well.

Here, although a P-SiOC film having a dielectric constant (k) of 2.9, for example, is used for the interlayer insulating films 2 and 4, an organic film such as a TEOS film or a poly (arylene ether) (PAE) film, or a porous silica film or the like may be used, instead. Although a tantalum nitride (TaN) film is used for the barrier metal film 6, titanium nitride (TiN), titanium (Ti), tantalum (Ta), niobium (Nb), or the like may be used, instead.

As described above, according to the semiconductor device of the first embodiment and the method of fabricating the same, the semiconductor device 90 includes the wiring member 3, which is used as a wiring layer, the electrode terminal portion 50, which is connected to the wiring member 3, and the wiring portion 60. The upper portion and the side surface of the wiring member 8, which is made of Cu (copper), in each of the electrode terminal portion 50 and the wiring portion 60 are coated with the coating metal film 9, which is made of Au (gold). The wiring member 8 is buried by using the electrolytic plating in the opening portions 23 and 24 formed while being surrounded by the resist film 22. The coating metal film 9 is formed on the wiring member 8 in such a manner as to cover the clearance 41, which is formed due to the shrinkage of the resist film 22, by using the electrolytic plating.

Accordingly, it is made possible to greatly suppress deterioration and a change in quality of the side surface portion due to oxidization or contamination of the side surface portion of the Cu (copper) wiring layer (wiring member 8) provided to the uppermost layer. Thus, the semiconductor device 90, which includes the highly reliable Cu (copper) wiring, can be provided. Moreover, the etching amount of the side surface portion of the Cu (copper) wiring layer provided to the uppermost layer does not have to be taken into consideration. Thus, the design rule (half-pitch width of wiring) of the wiring layer can be reduced, and the semiconductor device 90, which is highly integrated, can be provided.

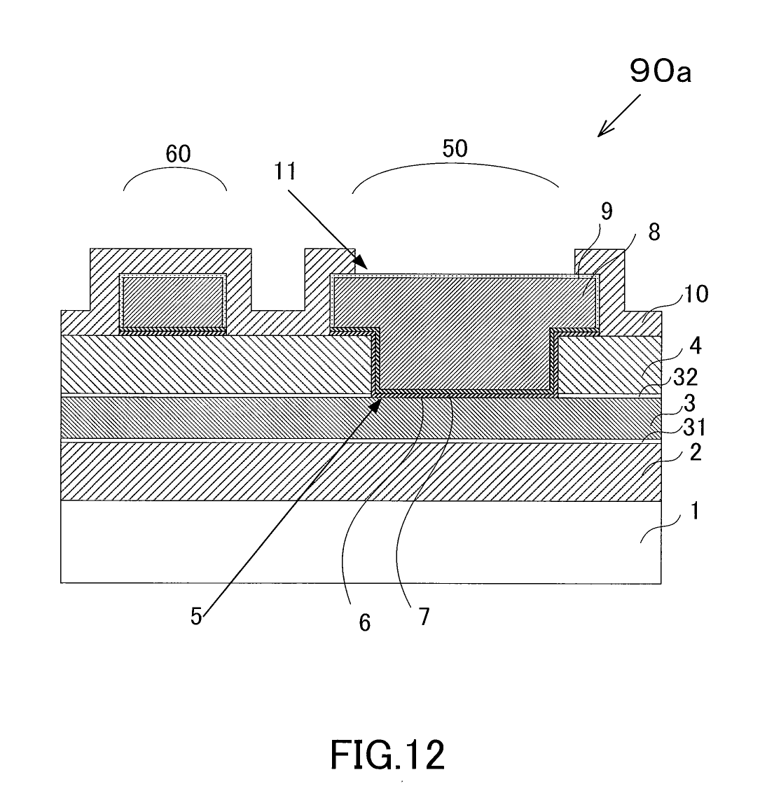

Note that, the wiring member 3 is provided on the interlayer insulating film 2, and the interlayer insulating film 4 is provided on the wiring member 3 in the first embodiment, but the invention is not necessarily limited to this configuration. As in the case of a semiconductor device 90a shown in FIG. 12, for example, a cap film 31 may be provided between the interlayer insulating film 2 and the wiring member 3. Moreover, a cap film 32 may be provided between the wiring member 3 and the interlayer insulating film 4. In a case where the interlayer insulating film 2 and the interlayer insulating film 4 are each made of a Low-k member, for example, a SiCN film or a PE-CVD film or the like is preferably used for the cap film 31 and the cap film 32. Here, the surface protection film 10 is provided on the electrode terminal portion 50 and the wiring portion 60.

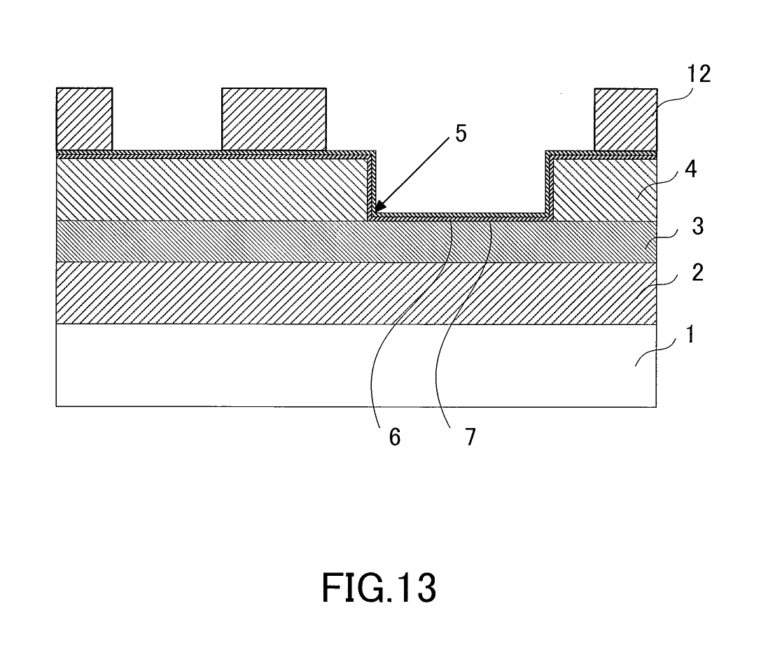

Next, a method of fabricating a semiconductor device, according to a second embodiment will be described with reference to the relevant drawings. FIGS. 13 to 17 are cross-sectional views each showing a fabrication process of the semiconductor device. In the second embodiment, the method of forming the coating metal film is changed.

Hereinafter, a portion with the same configuration in the first embodiment is provided with the same numeral, a description of the portion will not be repeated, and only a portion with a different configuration is described.

As shown in FIG. 13, after the seed metal film 7 is formed in the same manner as the first embodiment, an insulating film 12 is formed on the seed metal 7. After formation of a not-shown resist film by using well-known lithography, the insulating film 12 is etched by RIE, for example, using the resist film as a mask. Then, the resist film is removed.

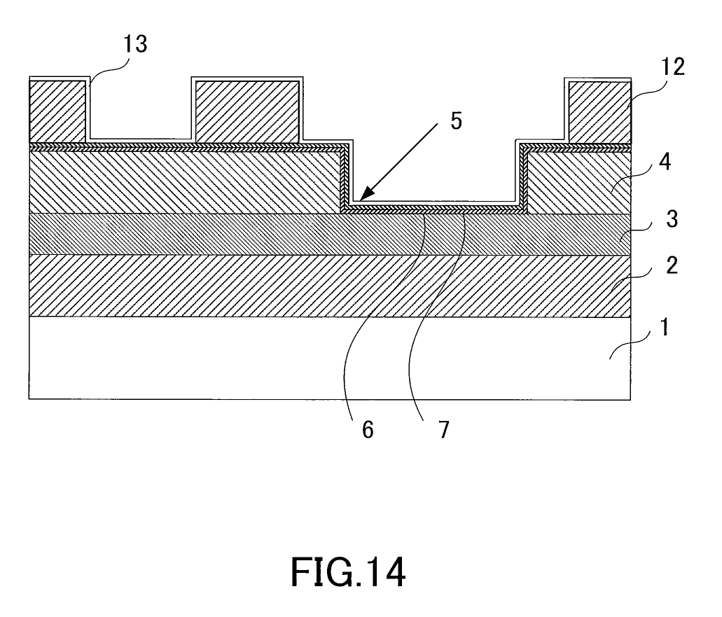

Next, as shown in FIG. 14, an insulating film 13, which has a film quality different from that of the insulating film 12, is formed on the seed metal film 7 and the insulating film 12. A silicon dioxide film (SiO2 film) is used for the insulating film 12 and a silicon nitride film (SiN film) is used for the insulating film 13, for example.

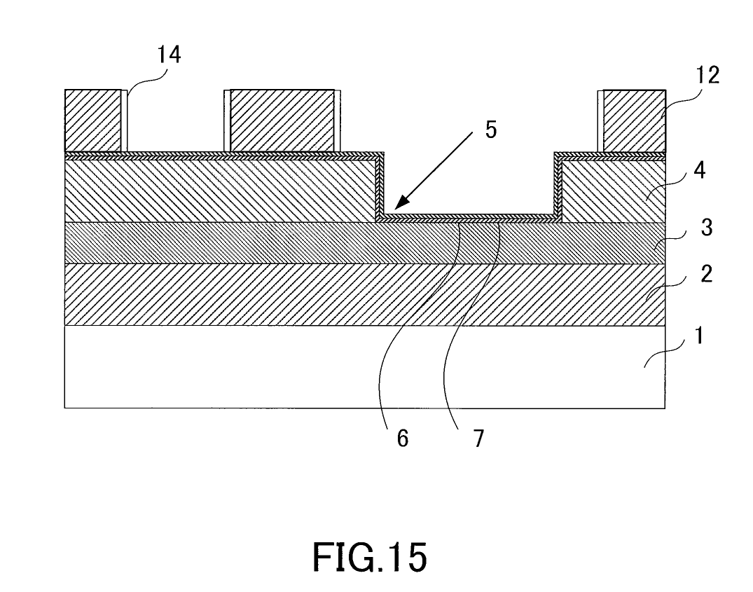

Subsequently, as shown in FIG. 15, the insulating film 13 is etched by RIE, for example, while the portions of the insulating film 13 on sidewall portions of the insulating film 12 are left. As a result of the processing, a sidewall insulating film 14, which is made of the insulating film 13, is formed on each of the sidewall portions of the insulating film 12.

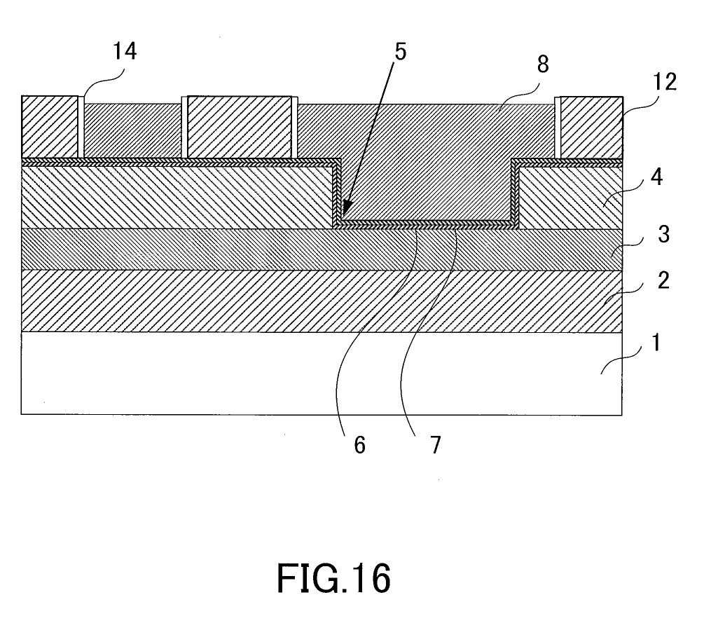

Next, as shown in FIG. 16, the wiring member 8, which is made of Cu (copper), is buried in the opening portions by using the first electrolytic plating in the same manner as the first embodiment.

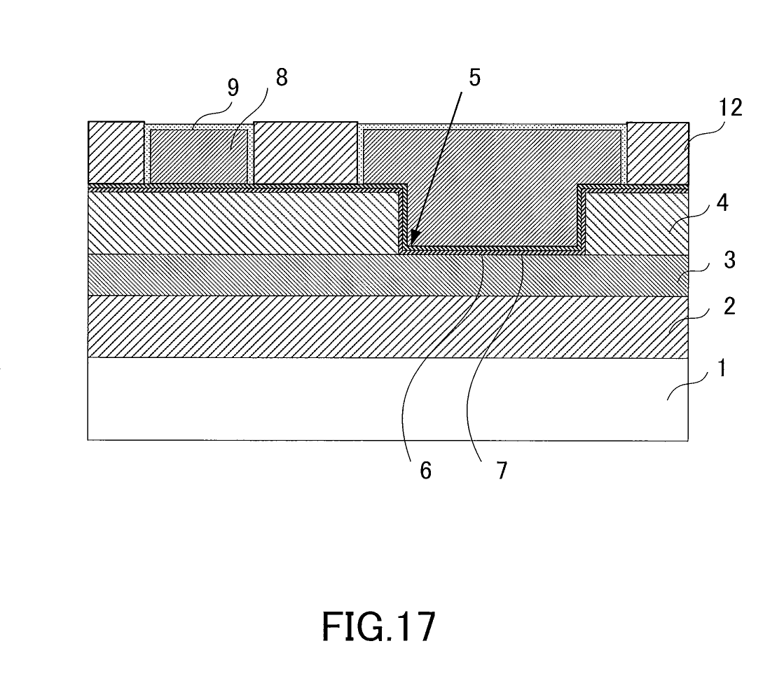

Next, as shown in FIG. 17, the clearance 41 is formed by selectively etching the sidewall insulating film 14 in the same manner as the first embodiment by using dry etching (plasma etching using nitrogen added Freon gas, for example) having a higher etching rate for the sidewall insulating film 14 than for the insulating film 12.

After formation of the clearance 41, the coating metal film 9, which is made of Au (gold), is formed on the upper portion and the side surface of the wiring member 8 in such a manner as to cover the clearance 41 by using the second electrolytic plating. For example, after the insulating film 12 is etched using the dry etching, the seed metal film 7 and the barrier metal film 6 are etched using the coating metal film 9 as a mask. A well-known technique is used to perform fabrication after this fabrication process. Thus, explanation of the fabrication after this fabrication process will be omitted herein.

As described above, in the method of fabricating the semiconductor device, according to the second embodiment, the semiconductor device 90 includes the wiring member 3, which is used as a wiring layer, the electrode terminal portion 50, which is connected to the wiring member 3, and the wiring portion 60. The upper portion and the side surface of the wiring member 8, which is made of Cu (copper), in each of the electrode terminal portion 50 and the wiring portion 60 are coated with the coating metal film 9, which is made of Au (gold). Electrolytic plating is used to form the wiring member 8 and the coating metal film 9. The wiring member 8 is buried by using electrolytic plating in the opening portions formed by etching the insulating film 12. The coating metal film 9 is formed on the wiring member 8 by electrolytic plating in such a manner as to cover the clearance 41, which is formed by etching the sidewall insulating film 14.

Accordingly, it is made possible to greatly suppress deterioration and a change in quality of the side surface portion due to oxidization or contamination of the side surface portion of the Cu (copper) wiring layer (wiring member 8) provided to the uppermost layer. Thus, the semiconductor device 90, which includes the highly reliable Cu (copper) wiring, can be provided. Moreover, the etching amount of the side surface portion of the Cu (copper) wiring layer provided to the uppermost layer does not have to be taken into consideration. Thus, the design rule (half-pitch width of wiring) of the wiring layer can be reduced, and the semiconductor device 90, which is highly integrated, can be provided.

Note that, the barrier metal film 6 and the seed metal film 7 are provided between the wiring member 3 and the wiring member 8 in the embodiments, but the invention is not necessarily limited to this configuration. For example, the barrier metal film 6 may be omitted by adding a different metal species having a faster diffusion rate than Cu (copper) to Cu (copper) serving as the wiring layer.

While certain embodiments have been described, these embodiments have been presented by way of example only, and are not intend to limit the scope of the inventions. Indeed, the novel embodiments described herein may be embodied in a variety of the other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a first wiring member provided on a first interlayer insulating film on a semiconductor substrate and used as a wiring layer;
an opening portion provided in a second interlayer insulating film on the first wiring member; and
an electrode terminal portion provided on the opening portion and the second interlayer insulating film around the opening portion, the electrode terminal portion having a barrier metal film in contact with the first wiring member, a seed metal film and a second wiring member which are formed and stacked so as to cover the opening portion, the electrode terminal portion having a coating metal film which is formed on an upper portion and a side portion of the second wiring member.

2. The semiconductor device according to claim 1, further comprising
a wiring portion provided away from the electrode terminal portion on the second interlayer insulating film, the wiring portion having the barrier metal film, the seed metal film and the second wiring member which are formed and stacked, the wiring portion having the coating metal film which is formed on an upper portion and a side surface of the second wiring member.

3. The semiconductor device according to claim 1, wherein
the second wiring member is made of Cu (copper), and
the coating metal film is made of Au (gold).

4. The semiconductor device according to claim 1, wherein
the first wiring member is made of any one of Cu (copper), Al (aluminum), Al—Cu and Al—Si—Cu.

5. The semiconductor device according to claim 1, wherein
the barrier metal film is made of any one of tantalum nitride (TaN), titanium nitride (TiN), titanium (Ti), tantalum (Ta) and niobium (Nb).

6. The semiconductor device according to claim 1, wherein
the first and second interlayer insulating films are each made of any one of a P-SiOC film, a TEOS film, a poly (arylene ether) film and a porous silica film.

7. The semiconductor device according to claim 1, further comprising:
a first cap film provided between the first interlayer insulating film and the first wiring member; and
a second cap film provided between the first wiring member and the second interlayer insulating film.

8. The semiconductor device according to claim 1, wherein
the electrode terminal portion is connected to an external terminal via a bonding wire, and
the semiconductor device is resin-sealed.

9. A method of fabricating a semiconductor device, comprising the steps of:
forming a first wiring member on a first interlayer insulating film on a semiconductor substrate;
forming a first opening portion by etching a second interlayer insulating film provided on the first wiring member;
forming and stacking a barrier metal film and a seed metal film on the first opening portion and the second interlayer insulating film;
forming a resist film having a second opening portion on the first opening portion and the seed metal film around the first opening portion;
burying a second wiring member in contact with the seed metal film in the second opening portion by using electrolytic plating;
forming a clearance between the second wiring member and the resist film by subjecting the resist film to a heat treatment so as to cause the resist film to shrink;
forming a coating metal film by using electrolytic plating on an upper portion and a side surface of the second wiring member so as to cover the clearance; and
removing the resist film and etching the exposed seed metal film and the barrier metal film by using the coating metal film as a mask.

10. The method according to claim 9, wherein
the second wiring member is made of Cu (copper), and
the coating metal film is made of Au (gold).

11. The method according to claim 9, wherein
the first wiring member is made of any one of Cu (copper), All (aluminum), Al—Cu and Al—Si—Cu.

12. The method according to claim 9, wherein
the barrier metal film is made of any one of tantalum nitride (TaN), titanium nitride (TiN), titanium (Ti), tantalum (Ta) and niobium (Nb).

13. The method according to claim 9, wherein
the first and second interlayer insulating films are each made of any one of a P-SiOC film, a TEOS film, a poly (arylene ether) film and a porous silica film.

14. A method of fabricating a semiconductor device, comprising the steps of:
forming a first wiring member on a first interlayer insulating film on a semiconductor substrate;
forming a first opening portion by etching a second interlayer insulating film provided on the first wiring member;
forming and stacking a barrier metal film and a seed metal film on the first opening portion and the second interlayer insulating film;
forming a first insulating film on the seed metal film;
forming a second opening portion on the first opening portion and the seed metal film around the first opening portion by etching the first insulating film;
forming a second insulating film on the second opening portion and the first insulating film;
forming a sidewall insulating film by anisotropically etching the second insulating film so as to leave the second insulating film on a side surface of the first insulating film;
burying a second wiring member whose bottom portion is in contact with the seed metal film and whose side surface is in contact with the sidewall insulating film in the second opening portion by using electrolytic plating;
forming a clearance between the second wiring member and the first insulating film by etching the sidewall insulating film;
forming a coating metal film by using electrolytic plating on an upper portion and a side surface of the second wiring member so as to cover the clearance; and
etching the first insulating film, and etching the exposed seed metal film and the barrier metal film by using the coating metal film as a mask.

15. The method according to claim 14, wherein
the second wiring member is made of Cu (copper), and
the coating metal film is made of Au (gold).

16. The method according to claim 14, wherein
the first wiring member is made of any one of Cu (copper), Al (aluminum), Al—Cu and Al—Si—Cu.
